(19) United States
(12) Patent Application Publication
(10) Pub. No.: US 2025/0006474 A1
(43) Pub. Date: Jan. 2, 2025

(54) INTERCONNECT CAPPING WITH INTEGRATED PROCESS STEPS

(71) Applicant: Applied Materials, Inc., Santa Clara, CA (US)

(72) Inventors: Naomi YOSHIDA, Sunnyvale, CA (US); Nobuyuki SASAKI, Santa Clara, CA (US); Yoichi SUZUKI, Funabashi-shi (JP); Tomoyuki TADA, Chiba (JP); Balasubramanian PRANATHARTHIHARAN, Santa Clara, CA (US)

(21) Appl. No.: 18/216,432

(22) Filed: Jun. 29, 2023

(51) Int. Cl. H01J 37/32; C23C 16/02; C23C 16/24; C23C 16/34; C23C 16/40; C23C 16/50; H01L 21/768

(52) U.S. Cl. CPC H01J 37/32899; C23C 16/0227; C23C 16/24; C23C 16/345; C23C 16/402; C23C 16/50; H01J 37/32357; H01J 37/32743; H01L 21/76834; H01L 21/7685; H01J 2237/3321; H01J 2237/335

(57) ABSTRACT

A cluster tool for forming an interconnection structure includes a pre-clean chamber, a selective chemical vapor deposition (CVD) chamber, a plasma-enhanced CVD (PECVD) chamber, one or more transfer chambers coupled to the pre-clean chamber, the selective CVD chamber, and the PECVD chamber, and configured to transfer the interconnection structure between the pre-clean chamber, the selective CVD chamber, and the PECVD chamber without breaking vacuum environment, and a controller configured to cause pre-cleaning of an exposed surface of a metal layer formed within a first dielectric layer of the interconnection structure in the pre-clean chamber, selective deposition of a cap layer on the pre-cleaned surface of the metal layer in the selective CVD chamber, and deposition of deposit a second dielectric layer on the cap layer and an exposed surface of the first dielectric layer in the PECVD chamber.

### BACKGROUND

### Field

Embodiments of the present disclosure generally relate to a method of forming an interconnection structure for semiconductor applications.

### Description of the Related Art

As dimensions of integrated circuit (IC) components in, for example, 3 dimensional (3D) NAND peripheral complementary metal-oxide semiconductor (CMOS) devices, are reduced (e.g., to sub-micron dimensions), copper (Cu) wires have been used to fabricate such components due to its low sheet resistance and high resistance to electromigration (EM) in place of aluminum (Al). A typical back-end-of-line (BEOL) interconnect wire includes a copper (Cu) wire that is encapsulated by a metal cap layer to improve EM performance, and a dielectric layer as a diffusion barrier layer.

Conventionally, a dielectric layer (e.g., silicon carbon nitride (SiCN)) deposited in a different cluster tool from a cluster tool in which a metal cap layer (e.g., cobalt (Co)) is deposited on the cupper (Cu) interconnect. To reduce oxidation of the metal cap layer, a wafer may be transferred via a nitrogen (N₂)-purged front opening unified pod (FOUP) between the cluster tools. However, the oxidation of the metal cap layer cannot be eliminated and thus a pre-cleaning process of the metal cap layer prior to deposition of a dielectric layer may needed, which damages underlying layers. Further, queue times of the cluster tools need to be controlled.

Therefore, there is a need for methods and systems for forming metal interconnects with a metal cap layer and a dielectric layer in simplified steps without exposure to an ambient environment.

### SUMMARY

Embodiments of the present disclosure provide a cluster tool for forming an interconnection structure. The cluster tool includes a pre-clean chamber configured to pre-clean an exposed surface of a metal layer formed within a first dielectric layer of the interconnection structure, a selective chemical vapor deposition (CVD) chamber configured to selectively deposit a cap layer on the pre-cleaned surface of the metal layer, a plasma-enhanced CVD (PECVD) chamber configured to deposit a second dielectric layer on the cap layer and an exposed surface of the first dielectric layer, one or more transfer chambers coupled to the pre-clean chamber, the selective CVD chamber, and the PECVD chamber, and configured to transfer the interconnection structure between the pre-clean chamber, the selective CVD chamber, and the PECVD chamber without breaking vacuum environment, and a controller configured to cause the pre-cleaning of the metal layer in the pre-clean chamber, the selective deposition of the cap layer in the selective CVD chamber, and the deposition of the second dielectric layer in the PECVD chamber.

Embodiments of the present disclosure provide a method of forming an interconnection structure. The method includes performing a pre-clean process to remove oxides formed on an exposed surface of a metal layer formed within a first dielectric layer of the interconnection structure in a pre-clean chamber, performing a selective deposition process to deposit a cap layer on the pre-cleaned surface of the metal layer in a selective chemical vapor deposition (CVD) chamber, and performing a blanket deposition process to deposit a second dielectric layer on the cap layer and an exposed surface of the first dielectric layer in a plasma-enhanced CVD (PECVD) chamber, wherein the pre-clean process, the selective deposition process, and the blanket deposition process are performed in a cluster tool without exposure to an ambient environment exterior to the cluster tool.

Embodiments of the present disclosure provide a method of forming an interconnection structure. The method includes performing a selective deposition process to deposit a cap layer on an exposed surface of a metal layer formed within a first dielectric layer of the interconnection structure in a selective chemical vapor deposition (CVD) chamber, and performing a blanket deposition process to deposit a second dielectric layer on the cap layer and an exposed surface of the first dielectric layer in a plasma-enhanced CVD (PECVD) chamber, wherein the selective deposition process and the blanket deposition process are performed in a cluster tool without exposure to an ambient environment exterior to the cluster tool.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber cluster tool, according to one or more embodiments of the present disclosure.

FIG. 2 depicts a flow diagram illustrating a method for fabricating an interconnection structure according to one embodiment of the present disclosure.

FIGS. 3A, 3A′, 3B, 3B′, 3C, 3C′, 3D, and 3D′ are cross-sectional views of a portion of a semiconductor structure corresponding to various states of the method of FIG. 2.

To facilitate understanding of the embodiments, identical reference numerals have been used, where possible, to designate identical elements that are common to the figures. It is contemplated that elements and features of one embodiment may be beneficially incorporated in other embodiments without further recitation.

### DETAILED DESCRIPTION

Systems and methods for capping a back-end-of-line (BEOL) interconnect wire (e.g., copper (Cu)) with a metal cap layer (e.g., cobalt (Co)) and a dielectric layer (e.g., silicon carbon nitride (SiCN)) integrated in a single cluster tool without exposure to an ambient environment exterior to the cluster tool are provided. Due to elimination of exposure to an ambient environment, contamination of the metal cap layer prior to deposition of the dielectric layer can be avoided, which leads to improved adhesion of the dielectric layer on the metal cap layer, and thus improved time dependent dielectric breakdown (TDDB) lifetime of a low-k dielectric layer that surrounds the interconnect wire. Further, the use of a metal cap layer (e.g., cobalt (Co)) between a metal layer (e.g., copper (Cu)) and a dielectric layer improves electromigration (EM) performance of the metal layer.

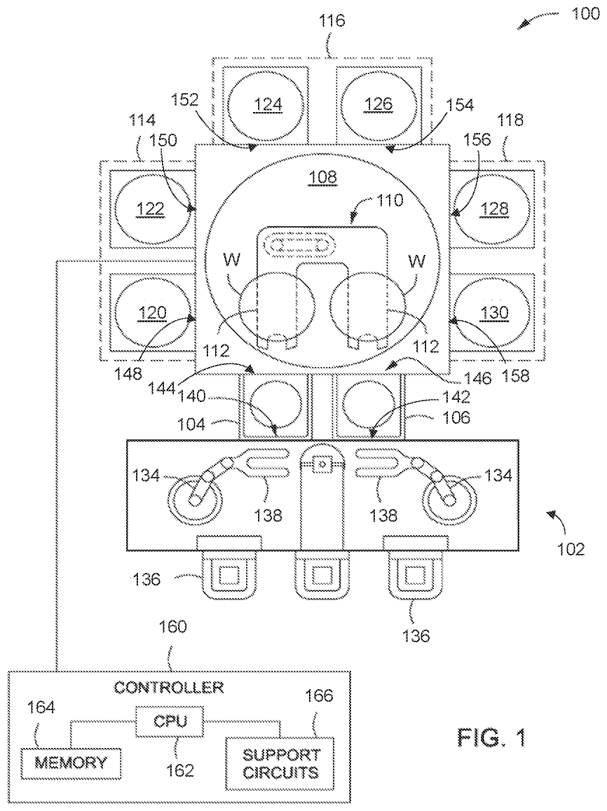

FIG. 1 is a schematic top view of a multi-chamber cluster tool 100, according to one or more embodiments of the present disclosure. The cluster tool 100 generally includes a factory interface 102, load lock chambers 104, 106, a transfer chamber 108, a transfer robot 110 having one or more transfer blades 112 (two shown), and one or more twin chamber processing systems 114, 116, 118 (three shown), each including two processing chambers 120 and 122, 124 and 126, 128 and 130. Each of the twin chamber processing systems 114, 116, 118 includes independent processing volumes that may be isolated from each other and may share resources (e.g., process gas supply, a vacuum pump) between the two processing chambers. As detailed herein, substrates W in the cluster tool 100 can be processed in and transferred between the various chambers without exposing the substrates W to an ambient environment exterior to the cluster tool 100 (e.g., an atmospheric ambient environment such as may be present in a fab). For example, the substrates W can be processed in and transferred between the various chambers maintained at a low pressure (e.g., less than or equal to about 300 Torr) or vacuum environment without breaking the low pressure or vacuum environment among various processes performed on the substrates W in the cluster tool 100. Accordingly, the cluster tool 100 may provide for an integrated solution for some processing of substrates W.

Examples of a processing system that may be suitably modified in accordance with the teachings provided herein include the Centura® or Producer® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates W. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates W from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150, 152, 154, 156, and 158 coupled to processing chambers 120, 122, 124, 126, 128, 130. The ports 144, 146, 148, 150, 152, 154, 156, 158 can be, for example, slit valve openings with slit valves for passing substrates W therethrough by the transfer robot 110 and for providing a seal between respective chambers to prevent a gas from passing between the respective chambers. Generally, any port is open for transferring a substrate therethrough. Otherwise, the port is closed.

The load lock chambers 104, 106, the transfer chamber 108, and the processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chamber 108 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 110 transfers the substrate from the load lock chamber 104 or 106 into the transfer chamber 108 through the port 144 or 146. The transfer robot 110 is then capable of transferring the substrate to and/or between any of the processing chambers 120, 122, 124, 126, 128, 130 through the respective ports 148, 150, 152, 154, 156, 158 for processing. The transfer of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 124, 126, 128, 130 can be capable of performing deposition processes. The processing chamber 120 may be a Selectra™ Etch chamber available from Applied Materials of Santa Clara, Calif. The processing chamber 122 may be an Aktiv™ Preclean (APC) chamber available from Applied Materials of Santa Clara, Calif. The processing chambers 124 and 126 may be a Volta® Cobalt CVD chambers available from Applied Materials of Santa Clara, Calif. The processing chamber 128 may be a Blok™ PECVD chamber available from Applied Materials of Santa Clara, Calif.

A system controller 160 is coupled to the cluster tool 100 for controlling the cluster tool 100 or components thereof. For example, the system controller 160 may control the operation of the cluster tool 100 using a direct control of the chambers 104, 106, 108, 120, 122, 124, 126, 128, 130 of the cluster tool 100 or by controlling controllers associated with the chambers 104, 106, 108, 120, 122, 124, 126, 128, 130. In operation, the system controller 160 enables data collection and feedback from the respective chambers to coordinate performance of the cluster tool 100.

The system controller 160 generally includes a central processing unit (CPU) 162, memory 164, and support circuits 166. The CPU 162 may be one of any form of a general-purpose processor that can be used in an industrial setting. The memory 164, or non-transitory computer-readable medium, is accessible by the CPU 162 and may be one or more of memory such as random access memory (RAM), read only memory (ROM), floppy disk, hard disk, or any other form of digital storage, local or remote. The support circuits 166 are coupled to the CPU 162 and may comprise cache, clock circuits, input/output subsystems, power supplies, and the like. The various methods disclosed herein may generally be implemented under the control of the CPU 162 by the CPU 162 executing computer instruction code stored in the memory 164 (or in memory of a particular processing chamber) as, for example, a software routine. When the computer instruction code is executed by the CPU 162, the CPU 162 controls the chambers to perform processes in accordance with the various methods.

Other processing systems can be in other configurations. For example, more or fewer processing chambers may be coupled to a transfer apparatus. In the illustrated example, the transfer apparatus includes the transfer chamber 108. In other examples, more or fewer transfer chambers (e.g., one transfer chamber) and/or more or fewer holding chambers (e.g., no holding chambers) may be implemented as a transfer apparatus in a processing system.

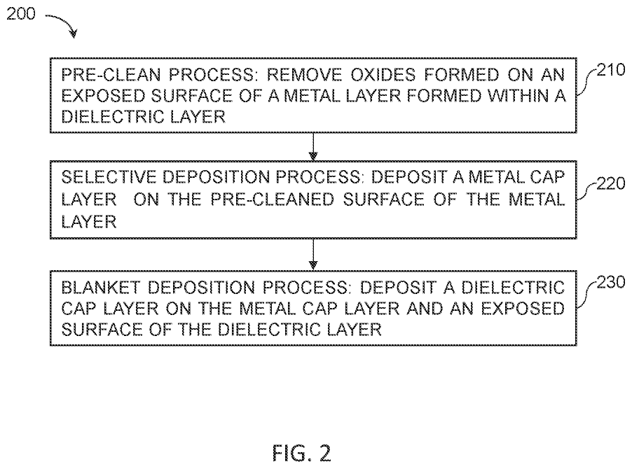

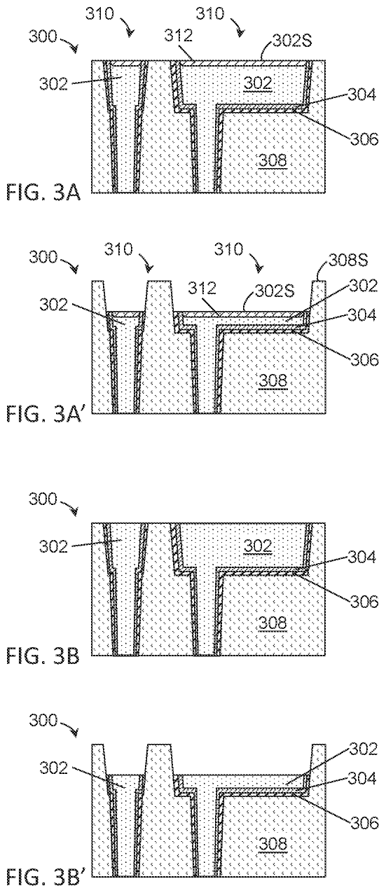

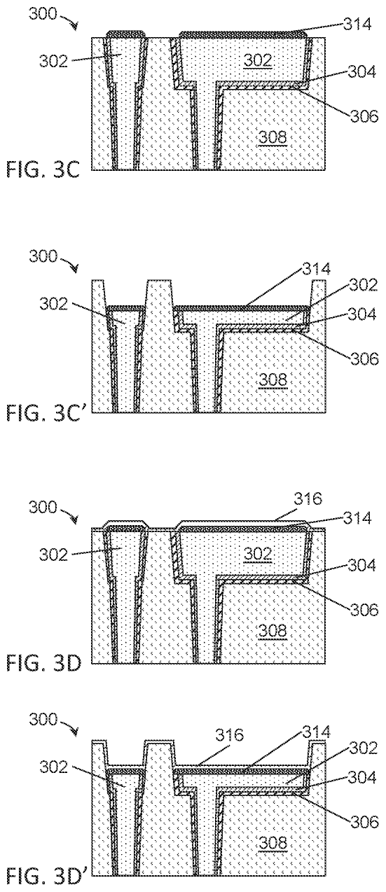

FIG. 2 depicts a process flow diagram of a method 200 of forming a semiconductor structure 300 that may include dual damascene interconnection structures utilized in the back end of line (BEOL), according to one or more embodiments of the present disclosure. FIGS. 3A, 3A′, 3B, 3B′, 3C, 3C′, 3D, and 3D′ are cross-sectional views of a portion of the semiconductor structure 300 corresponding to various states of the method 200. It should be understood that FIGS. 3A, 3A′, 3B, 3B′, 3C, 3C′, 3D, and 3D′ illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

As shown in FIG. 3A, the semiconductor structure 300 includes metal layers 302 each encapsulated in a metal seed layer 304 and in a barrier layer and a liner (shown combined in figures) 306 within a dielectric layer 308 formed on a substrate (not shown). In some embodiments, the metal layer 302 is recessed from a top surface 308S of the dielectric layer 308, as shown in FIG. 3A′.

The dielectric layer 308 may be formed of silicon oxide (SiO₂) or a low-k dielectric material, such as carbon-containing silicon oxides (SiOC), such as Black Diamond® dielectric film available from Applied Materials, Inc., or other low-k polymers, such as polyamides, and patterned with openings 310 (e.g., damascene features, such as a trench over a via) by an appropriate lithographic method.

The barrier layer may be formed of transition metal such as tantalum (Ta) or titanium (Ti), and nitrides thereof such as tantalum nitride (TaN) or titanium nitride (TIN). The liner may be formed of cobalt (Co) or ruthenium (Ru). The barrier layer and the liner 306 are deposited on the patterned dielectric layer 308 by an appropriate deposition process, such as chemical vapor deposition (CVD) or physical vapor deposition (PVD).

The metal layer 302 and the metal seed layer 304 may be formed of metal, such as copper (Cu), copper-aluminum (CuAl) alloy (0.1-5 at. % Al), or copper-manganese (CuMn) alloy (0.1-5 at. % Mn). Due to the low conductivity and poor nucleation of metal (e.g., copper (Cu)) on the barrier layer 306 (e.g., Ta/TaN), the metal seed layer 304 may be deposited to ensure defect-free filling of the openings 310 with metal in a metallization process by a CVD, a PVD, an atomic layer deposition (ALD), an electrophoretic deposition (ED) process, or other suitable deposition process.

The semiconductor structure 300 may be planarized by a chemical mechanical polishing (CMP) process to remove over-filled metal (e.g., copper (Cu)).

The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate may have various dimensions, such as 200 mm, 300 mm or 450 mm diameter wafers, as well as, rectangular or square panels. Unless otherwise noted, embodiments and examples described herein are conducted on substrates with a 300 mm diameter or a 450 mm diameter.

The method 200 begins with block 210, in which a pre-clean process is performed to remove oxides 312 (e.g., copper oxide CuOₓ) formed on an exposed surface 302S of the metal layer 302, as shown in FIGS. 3B and 3B′ The pre-clean process may be performed in a pre-clean chamber, such as the processing chamber 122 in FIG. 1 or an Aktiv™ Preclean (APC) chamber available from Applied Materials of Santa Clara, Calif., which may be suitably adapted in a cluster tool, such as the cluster tool 100 shown in FIG. 1 or a Producer® cluster tool available from Applied Materials of Santa Clara, Calif.

The pre-clean process includes providing reactive hydrogen radicals H* generated by a remote plasma source in the pre-clean chamber. Cleaning with hydrogen radicals H* has reduced damage to the underlying dielectric layer 308 as compared to cleaning with hydrogen ions (H⁺). In some embodiments, an inert gas, such as argon (Ar) or helium (He), is also provided in the pre-clean chamber.

Reducing the oxides 312 on the surface 302S of the metal layer 302 may increase a metallic surface of the metal layer 302, which improves adhesion of a metal cap layer thereon in the selective deposition process in block 220.

In block 220, a selective deposition process is performed to deposit a cap layer 314 on the pre-cleaned surface of the metal layer 302, as shown in FIGS. 3C and 3C′. The selective deposition process may include a selective CVD deposition process, performed in a selective CVD chamber, such as the processing chamber 124 or 126, or a Volta® Cobalt CVD chamber available from Applied Materials of Santa Clara, Calif., which may be suitably adapted in the cluster tool. The selective deposition process in block 220 is performed within the cluster tool without exposing the semiconductor structure 300 to an ambient environment exterior to the cluster tool subsequent to the pre-clean process in block 210.

The cap layer 314 is deposited to improve wiring reliability, e.g., electromigration (EM) performance, of an interconnect (e.g., the metal layer 302) at the completion of a metal level in the back-end-of-line (BEOL). EM (i.e., mass metal transport stressed by high current density) in thin metal interconnects may occur through diffusion, at an interface between a metal and a dielectric layer, creating vacancies of atoms, and voids or hillocks in the interconnect. Void formation may result in open circuits and increases line resistance. Hillock formation may result in short circuits between adjacent interconnects. The cap layer 314 between the metal layer 302 and a dielectric layer may decrease EM between the metal layer 302 and the dielectric layer, and thus improve EM resistance.

The cap layer 314 may be formed of a metal cap layer selectively deposited directly on the pre-cleaned surface of the metal layer 302. The metal cap layer may include cobalt (Co), titanium (Ti), manganese (Mn), ruthenium (Ru), cobalt tungsten phosphide (CoWP), tungsten (W), nickel (Ni), platinum (Pt), or copper (Cu) alloy thereof, such as titanium-copper (TiCu) alloy, and have a thickness of between about 1 nm and about 10 nm, for example, about 2 nm. In some embodiments, the cap layer 314 further includes a dielectric cap layer selectively deposited on the metal cap layer. The dielectric cap layer may include dielectric materials, such as silicon nitride (SiN), a nitrogen-doped carbon-containing silicon (e.g., silicon carbon nitride (SiCN)), or a carbon-containing silicon (e.g., silicon carbide (SiC)).

In some other embodiments, the cap layer 314 is formed of a dielectric cap layer selectively deposited directly on the pre-cleaned surface of the metal layer 302. The dielectric cap layer may include dielectric material, such as silicon nitride (SiN), a nitrogen-doped carbon-containing silicon (e.g., silicon carbon nitride (SiCN)), or a carbon-containing silicon (e.g., silicon carbide (SiC))

In block 230, a blanket deposition process is performed to deposit a dielectric layer 316 on the cap layer 314 and an exposed surface of the dielectric layer 308, as shown in FIGS. 3D and 3D′. The blanket deposition process may include a plasma-enhanced CVD (PECVD) process, performed in a PECVD chamber, such as a BLOK™ PECVD chamber available from Applied Materials of Santa Clara, Calif., which may be suitably adapted and integrated with a pre-clean chamber such as an Aktiv™ Preclean (APC) chamber available from Applied Materials of Santa Clara, Calif. and a selective CVD chamber such as a Volta® Cobalt CVD chamber available from Applied Materials of Santa Clara, Calif. in the cluster tool. The blanket deposition process in block 230 is performed within the cluster tool without exposing the semiconductor structure 300 to an ambient environment exterior to the cluster tool subsequent to the selective deposition process in block 220.

In a conventional cluster tool, a processing chamber that is adapted to deposit a low-k dielectric material is not integrated with a pre-clean chamber such as an Aktiv™ Preclean (APC) chamber available from Applied Materials of Santa Clara, Calif. and a selective CVD chamber such as a Volta® Cobalt CVD chamber available from Applied Materials of Santa Clara, Calif. Thus, the semiconductor structure 300 needs to be transferred, subsequent to the selective deposition process in block 220, from one cluster tool to another cluster tool via a nitrogen-purged FOUP to minimize oxidation or some other impacts due to exposure to an ambient environment exterior to the cluster tool. Further, as the cap layer 314 (e.g., cobalt (Co)) is easily oxidized even in a nitrogen-purged FOUP, another pre-clean process may be performed to remove oxides and contaminants on an exposed surface of the cap layer 314 subsequent to the transfer via a nitrogen-purged FOUP. This pre-clean process may use a capacitively couple plasma (CCP) ammonia (NH₃) plasma, which damages the underlying dielectric layer 308 and/or increases a dielectric constant of the low-k dielectric material in the dielectric layer 308. Breakdown of the underlying dielectric layer 308 may result in short circuits between adjacent interconnects and increase resistance-capacitance (RC) delays.

In the cluster tool according to the embodiments described herein, a plasma-enhanced CVD (PECVD) chamber, such as a BLOK™ PECVD chamber available from Applied Materials of Santa Clara, Calif. is integrated with a pre-clean chamber such as an Aktiv™ Preclean (APC) chamber available from Applied Materials of Santa Clara, Calif. and a selective CVD chamber such as a Volta® Cobalt CVD chamber available from Applied Materials of Santa Clara, Calif., such that the semiconductor structure 300 can be transferred from the pre-clean chamber to the selective CVD chamber, and from the selective CVD chamber to the PECVD chamber without exposure to an ambient environment exterior to the cluster tool. Thus, oxidation of the cap layer 314 can be avoided, and no pre-clean process (by CCP ammonia (NH₃) plasma) to remove oxides of the cap layer 314. Further, there is no need for a FOUP with nitrogen flow capability or no need to control queue times in which the semiconductor structure 300 resides outside processing chambers or controlled environment.

Eliminating exposure to an ambient environment may enhance device reliability, e.g., a time dependent dielectric breakdown (TDDB) (i.e., a degradation of a dielectric due to an electric filed) lifetime of the dielectric layer 308, as no contamination (e.g., moisture or carbon) from exposure to an ambient environment on the cap layer 314 improves adhesion of the dielectric layer 316 thereon.

The dielectric layer 316 may be formed of a low-k dielectric material (e.g., a dielectric constant of about 5.5 or less) such as BLOK® low-k dielectric film, available from Applied Materials, Inc.

The dielectric layer 316 acts as a diffusion barrier layer to prevent diffusion of metal elements (e.g., copper (Cu)) from the metal layer 302, which may cause a short circuit or other device defects. The dielectric layer 316 may also act as an etch stop layer in subsequent patterning processes. The dielectric layer 316 may have a thickness of between about 1 nm and about 100 nm.

In some embodiments, the dielectric layer 316 includes an enhanced nitrogen interface (ENI) to improve reliability even further.

Subsequent to the blanket deposition process in block 230, other layers such as ILD (inter layer dielectric) layers (not shown) may be deposited on dielectric layer 316 in the same cluster tool or another cluster tool. During a transfer to another tool, the cap layer 314 is protected from oxidation by the dielectric layer 316.

The embodiments provided herein provide systems and methods for capping a back-end-of-line (BEOL) interconnect wire (e.g., copper (Cu)) with a metal cap layer (e.g., cobalt (Co)) and a dielectric layer (e.g., silicon carbon nitride (SiCN)) in a single cluster tool without exposure to an ambient environment exterior to the cluster tool. The use of the metal cap layer may improve electromigration (EM) performance of the interconnect wire. Due to elimination of exposure to an ambient environment, time dependent dielectric breakdown (TDDB) lifetime of a low-k dielectric layer that surrounds the metal layer may be improved. The process steps for capping an interconnect wire are integrated in a single cluster tool such that no queue time control are needed.

While the foregoing is directed to embodiments of the present disclosure, other and further embodiments of the disclosure may be devised without departing from the basic scope thereof, and the scope thereof is determined by the claims that follow.

What is claimed is:

1. A cluster tool for forming an interconnection structure, comprising:
a pre-clean chamber configured to pre-clean an exposed surface of a metal layer formed within a first dielectric layer of the interconnection structure;
a selective chemical vapor deposition (CVD) chamber configured to selectively deposit a cap layer on the pre-cleaned surface of the metal layer;
a plasma-enhanced CVD (PECVD) chamber configured to deposit a second dielectric layer on the cap layer and an exposed surface of the first dielectric layer;
one or more transfer chambers coupled to the pre-clean chamber, the selective CVD chamber, and the PECVD chamber, and configured to transfer the interconnection structure between the pre-clean chamber, the selective CVD chamber, and the PECVD chamber without breaking vacuum environment; and
a controller configured to cause the pre-cleaning of the metal layer in the pre-clean chamber, the selective deposition of the cap layer in the selective CVD chamber, and the deposition of the second dielectric layer in the PECVD chamber.

2. The cluster tool of claim 1, wherein the pre-cleaning of the exposed surface of the metal layer comprises providing reactive hydrogen radicals H* generated by a remote plasma source in the pre-clean chamber.

3. The cluster tool of claim 1, wherein
the metal layer comprises at least one of copper (Cu), copper-aluminum (CuAl) alloy, and copper-manganese (CuMn) alloy,
the first dielectric layer comprises silicon oxide (SiO₂) or a low-k dielectric material, and
the second dielectric layer comprises a low-k dielectric material.

4. The cluster tool of claim 1, wherein the cap layer comprises a metal cap layer selectively deposited on the pre-cleaned surface of the metal layer, the metal cap layer comprising at least one of cobalt (Co), titanium (Ti), manganese (Mn), ruthenium (Ru), cobalt tungsten phosphide (CoWP), tungsten (W), nickel (Ni), platinum (Pt), and copper (Cu) alloy thereof.

5. The cluster tool of claim 4, wherein the cap layer further comprises a first dielectric cap layer selectively deposited on the metal cap layer, wherein the first dielectric cap layer comprising at least one of silicon nitride, nitrogen-doped carbon-containing silicon, and a carbon-containing silicon.

6. The cluster tool of claim 1, wherein the cap layer comprises a second dielectric cap layer selectively deposited on the pre-cleaned surface of the metal layer, wherein the second dielectric cap layer comprises at least one of silicon nitride, nitrogen-doped carbon-containing silicon, and a carbon-containing silicon.

7. A method of forming an interconnection structure, comprising:
performing a pre-clean process to remove oxides formed on an exposed surface of a metal layer formed within a first dielectric layer of the interconnection structure in a pre-clean chamber;
performing a selective deposition process to deposit a cap layer on the pre-cleaned surface of the metal layer in a selective chemical vapor deposition (CVD) chamber; and
performing a blanket deposition process to deposit a second dielectric layer on the cap layer and an exposed surface of the first dielectric layer in a plasma-enhanced CVD (PECVD) chamber, wherein
the pre-clean process, the selective deposition process, and the blanket deposition process are performed in a cluster tool without exposure to an ambient environment exterior to the cluster tool.

8. The method of claim 7, wherein
the metal layer comprises at least one of copper (Cu), copper-aluminum (CuAl) alloy, and copper-manganese (CuMn) alloy,
the first dielectric layer comprises silicon oxide (SiO₂) or a low-k dielectric material, and
the second dielectric layer comprises a low-k dielectric material.

9. The method of claim 7, wherein the cap layer comprises a metal cap layer selectively deposited on the pre-cleaned surface of the metal layer, the metal layer comprising at least one of cobalt (Co), titanium (Ti), manganese (Mn), ruthenium (Ru), cobalt tungsten phosphide (CoWP), tungsten (W), nickel (Ni), platinum (Pt), and copper (Cu) alloy thereof.

10. The method of claim 9, wherein the cap layer further comprises a first dielectric cap layer selectively deposited on the metal cap layer, wherein the first dielectric cap layer comprising at least one of silicon nitride, nitrogen-doped carbon-containing silicon, and a carbon-containing silicon.

11. The method of claim 7, wherein the cap layer comprises a second dielectric cap layer selectively deposited on the pre-cleaned surface of the metal layer, wherein the second dielectric cap layer comprises at least one of silicon nitride, nitrogen-doped carbon-containing silicon, and a carbon-containing silicon.

12. The method of claim 7, wherein the pre-clean process comprises providing reactive hydrogen radicals H* generated by a remote plasma source in the pre-clean chamber.

13. The method of claim 7, wherein the selective deposition process comprises a selective CVD process.

14. The method of claim 7, wherein the blanket deposition process comprises a PECVD process.

15. A method of forming an interconnection structure, comprising:
performing a selective deposition process to deposit a cap layer on an exposed surface of a metal layer formed within a first dielectric layer of the interconnection structure in a selective chemical vapor deposition (CVD) chamber; and
performing a blanket deposition process to deposit a second dielectric layer on the cap layer and an exposed surface of the first dielectric layer in a plasma-enhanced CVD (PECVD) chamber, wherein
the selective deposition process and the blanket deposition process are performed in a cluster tool without exposure to an ambient environment exterior to the cluster tool.

16. The method of claim 15, wherein
the metal layer comprises at least one of copper (Cu), copper-aluminum (CuAl) alloy, and copper-manganese (CuMn) alloy,
the first dielectric layer comprises silicon oxide (SiO₂) or a low-k dielectric material, and
the second dielectric layer comprises a low-k dielectric material.

17. The method of claim 15, wherein the cap layer comprises a metal cap layer selectively deposited on the pre-cleaned surface of the metal layer, the metal cap layer comprising at least one of cobalt (Co), titanium (Ti), manganese (Mn), ruthenium (Ru), cobalt tungsten phosphide (CoWP), tungsten (W), nickel (Ni), platinum (Pt), and copper (Cu) alloy thereof.

18. The method of claim 17, wherein the cap layer further comprises a first dielectric cap layer selectively deposited on the metal cap layer, wherein the first dielectric cap layer comprising at least one of silicon nitride, nitrogen-doped carbon-containing silicon, and a carbon-containing silicon.

19. The method of claim 15, wherein the cap layer comprises a second dielectric cap layer selectively deposited on the pre-cleaned surface of the metal layer, wherein the second dielectric cap layer comprises at least one of silicon nitride, nitrogen-doped carbon-containing silicon, and a carbon-containing silicon.

20. The method of claim 15, wherein the selective deposition process comprises a selective CVD process, and the blanket deposition process comprises a PECVD process.
